(19) United States
(12) Patent Application Publication
(10) Pub. No.: US 2009/0207534 A1
(43) Pub. Date: Aug. 20, 2009

(54) MAGNETO-RESISTANCE EFFECT ELEMENT INCLUDING STACK WITH DUAL FREE LAYER AND MAGNETIZED SHIELD ELECTRODE LAYERS

(75) Inventors: Daisuke MIYAUCHI, Tokyo (JP); Koji SHIMAZAWA, Tokyo (JP); Tsutomu CHOU, Tokyo (JP); Takahiko MACHITA, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: TDK Corporation, Tokyo (JP)

(21) Appl. No.: 12/033,292

(22) Filed: Feb. 19, 2008

(51) Int. Cl. G11B 5/39; G11B 5/012; G01R 33/09; G11B 5/00

(52) U.S. Cl. 360/324.11

(57) ABSTRACT

A magneto-resistance effect element comprises; a magneto-resistance effect stack including an upper magnetic layer and a lower magnetic layer in which respective magnetization directions change in accordance with an external magnetic field, a non-magnetic intermediate layer sandwiched between the upper and lower magnetic layers, an upper gap adjustment layer and a lower gap adjustment layer provided at respective ends in the direction of stacking the magneto-resistance effect stack, an upper exchange coupling transmission layer configured to generate exchange coupling between the upper magnetic layer and the upper gap adjustment layer, and a lower exchange coupling transmission layer configured to generate exchange coupling between the lower magnetic layer and the lower gap adjustment layer; an upper shield electrode layer and a lower shield electrode layer which are provided to sandwich the magneto-resistance effect stack therebetween in the direction of stacking the magneto-resistance effect stack, wherein the upper shield electrode layer and the lower shield electrode layer supply sense current in the direction of stacking, and magnetically shield the magneto-resistance effect stack; and a bias magnetic layer which is provided on a surface of the magneto-resistance effect stack opposite to an air bearing surface, and wherein the bias magnetic layer applies a bias magnetic field to the upper and lower magnetic layers in a direction perpendicular to the air bearing surface, wherein the upper and lower shield electrode layers are each magnetized in a track width direction by a magnetization controller, and the upper and lower gap adjustment layers are composed of a material having a higher magnetic permeability and a lower saturation magnetic flux density than the upper and lower shield electrode layers respectively.

### BACKGROUND OF THE INVENTION

1. Field of the Invention

The present invention relates to a magneto-resistance effect element, and in particular to a element structure of a magneto-resistance effect element having dual free layer.

2. Description of the Related Art

Thin-film magnetic heads used in hard disk drives are constructed from a readout head having a reproducing element for reading and a write head having an inductive-type electromagnetic conversion device for writing. A giant magneto-resistance (GMR) element is known as the reproducing element of the thin film magnetic head. Conventionally, CIP (Current In Plane) GMR elements in which a sense current flows in a direction parallel to the film surface have been mainly used. Recently, however, in order to support ever higher recording densities, CPP (Current Perpendicular to the Plane) type magneto-resistance effect (MR) elements in which the sense current flows in a direction perpendicular to the film surface have been developed. Known examples of this type of element include TMR (Tunnel Magneto-resistance) elements utilizing TMR effects and CPP-GMR elements utilizing GMR effects. The TMR elements, in particular, have a higher magneto-resistance ratio than GMR-CPP elements, and are expected to produce a high output.

CPP elements include a magneto-resistance effect (MR) stack having a magnetic layer (free layer) in which the magnetization direction changes according to an external magnetic field, a magnetic layer (pinned layer) in which the magnetization direction is fixed, and a non-magnetic intermediate layer which is sandwiched between the pinned layer and the free layer. To fix the magnetization direction in the pinned layer, the MR stack is provided with an anti-ferromagnetic layer (pinning layer). The pinning layer is provided adjacent to the pinned layer, and fix the magnetization direction of the pinned layer by exchange coupling with the pinned layer. The MR stack may also be called a spin valve film. The magnetization direction in the free layer varies according to the external magnetic field, and a relative angle between the magnetization direction of the pinned layer and the magnetization direction of the free layer is changed. This causes variation in the electrical resistance to the sense current flowing perpendicular to the film surface of the spin valve film. Using this property, the external magnetic field is detected.

Meanwhile, in recent years, a need has arisen for further improvements in the recording density of hard disk drives. As a means to improve recording densities, reducing the layer thickness of the MR stack is indispensable. Hence, MR stacks that have a novel layer structure which differs from the above-described conventional spin-valve film structure have been proposed. For instance, “Current-in-Plane GMR Tri-layer Head Design for Hard-Disk Drives” (IEEE TRANSACTIONS ON MAGNETICS, Vol. 43, No. 2, February 2007) discloses, for a CIP element, an MR stack that includes a upper and lower magnetic layers in which the magnetization direction changes according to the external magnetic field, and a non-magnetic intermediate layer sandwiched between the upper magnetic layer and the lower magnetic layer. Since the magnetization directions of the upper and lower magnetic layers vary according to the external magnetic field, these layers may also be called free layers. A bias magnetic layer is provided on what is the opposite side of the MR stack when the MR stack is viewed from the opposite surface of the recording medium, and the bias magnetic field is applied in a direction perpendicular to the opposite surface of the recording medium. The magnetic field emitted from the bias magnetic layer causes the magnetization directions of the upper magnetic layer and the lower magnetic layer to maintain a constant angle relative to each other. When an external magnetic field is applied with the MR stack in this state, the magnetization directions of the upper and lower magnetic layers vary, thereby causing a change in the relative angle formed between the magnetization directions in the upper and lower magnetic layers. Thus, electrical resistance of sense current is changed. Use of this property allows variation in the external magnetic field to be detected. When this type of device structure that has the pair of free layers is applied to the CPP-type magneto-resistance effect (MR) element, the layer thickness of the MR stack is substantially reduced.

To improve accuracy in detection of the magnetic field by magneto-resistance effect elements of the type described above, the magnetization directions of the upper magnetic layer and the lower magnetic layer in the absence of a bias magnetic field must be anti-parallel. This can be easily realized by inserting a non-magnetic intermediate layer of Cu, Au, Ag, Ir, Rh, Ru, Cr or the like between the upper magnetic layer and the lower magnetic layer to generate anti-ferromagnetic exchange coupling between the upper magnetic layer and the lower magnetic layer. However, when the non-magnetic intermediate layer is composed of these materials, it is difficult to increase the magneto-resistance ratio. As a result, it is difficult to improve the output of the magneto-resistance effect element.

A TMR element having a large magneto-resistance ratio and that is capable of a high output is required to have a non-magnetic intermediate layer that is an insulating layer comprising of aluminum oxide (AlOₓ), magnesium oxide (MgO), or the like to obtain a tunneling effect. However, with these materials, it is extremely difficult to generate anti-ferromagnetic exchange coupling between the upper magnetic layer and the lower magnetic layer.

U.S. Pat. No. 6,169,647 records an arrangement in which the magnetization directions of the upper magnetic layer and the lower magnetic layer are set to be anti-parallel using two anti-ferromagnetic layers. However, to obtain useful effects, it is necessary that a layer thickness of the anti-ferromagnetic layer is 5 nm or more. Consequently, there is an undesired increase in the layer thickness of the MR stack. Also, while it is necessary to set the directions of the exchange coupling generated by the two anti-ferromagnetic layers to be anti-parallel, the heat treatment (annealing) to realize this arrangement is very difficult. Moreover, when the element size is reduced, the pinning function ceases to be sufficiently effective and it becomes difficult to partition the upper and lower magnetic layers into single domains. Consequently, there is problem in that Barkhausen noise which accompanies the movement in the magnetic domain walls of the upper and lower magnetic layers causes variation in the output characteristics.

### SUMMARY OF THE INVENTION

The present invention is for a CPP-type magneto-resistance effect element having dual free layer. The object of the present invention is to provide a CPP-type magneto-resistance effect element in which it is possible to realize anti-parallel magnetization state in a pair of free layers. A further object of the present invention is to improve detection properties of the above-described magneto-resistance effect element by improving the shielding effects of shield electrode layers and reducing variation in the magnetization directions in the free layers.

A magneto-resistance effect element comprises; a magneto-resistance effect stack including an upper magnetic layer and a lower magnetic layer in which respective magnetization directions change in accordance with an external magnetic field, a non-magnetic intermediate layer sandwiched between the upper and lower magnetic layers, an upper gap adjustment layer and a lower gap adjustment layer provided at respective ends in the direction of stacking the magneto-resistance effect stack, an upper exchange coupling transmission layer configured to generate exchange coupling between the upper magnetic layer and the upper gap adjustment layer, and a lower exchange coupling transmission layer configured to generate exchange coupling between the lower magnetic layer and the lower gap adjustment layer; an upper shield electrode layer and a lower shield electrode layer which are provided to sandwich the magneto-resistance effect stack therebetween in the direction of stacking the magneto-resistance effect stack, wherein the upper shield electrode layer and the lower shield electrode layer supply sense current in the direction of stacking, and magnetically shield the magneto-resistance effect stack; and a bias magnetic layer which is provided on a surface of the magneto-resistance effect stack opposite to an air bearing surface, and wherein the bias magnetic layer applies a bias magnetic field to the upper and lower magnetic layers in a direction perpendicular to the air bearing surface, wherein the upper and lower shield electrode layers are each magnetized in a track width direction by a magnetization controller, and the upper and lower gap adjustment layers are composed of a material having a higher magnetic permeability and a lower saturation magnetic flux density than the upper and lower shield electrode layers respectively.

According to the above construction, the upper and lower shield electrode layers are magnetized by the magnetization controller. Further, as a consequence of having magnetic permeability than higher the upper and lower shield electrode layers, the upper and lower gap adjustment layers are magnetized in directions parallel to the upper and lower shield electrode layers respectively. The upper magnetic layer is a free layer, and exchange couples with the upper gap adjustment layer via the upper exchange coupling transmission layer. The lower magnetic layer is a free layer, and exchange couples with the lower gap adjustment layer via the lower exchange coupling transmission layer. The magnetization directions of the upper magnetic layer and the lower magnetic layer are then anti-parallel in the absence of a bias magnetic field. A bias magnetic field emitted from the bias magnetic layer causes the magnetization direction of the upper magnetic layer and the magnetization direction of the lower magnetic layer to be substantially perpendicular when an external magnetic field is not being applied. Since various materials can be used as the non-magnetic intermediate layer, it is possible to obtain a high magneto-resistance ratio.

Further, since the upper and lower gap adjustment layers have a higher magnetic permeability and a lower saturation magnetic flux density than the upper and lower shield electrode layers, the magnetization of the upper and lower gap adjustment layers are saturated and provide a single domain structure. Hence, the upper and lower magnetic layers, which are exchange coupled with the upper and lower gap adjustment layers, can reduce the Barkhausen noise by forming the single domains and by reducing variation in the magnetization. It is thereby possible to maintain a more constant signal output from the magneto-resistance effect element. Since the magnetic flux density in the upper and lower shield electrode layers in regions adjacent to the upper and lower gap adjustment layers is lowered, the shielding effects of the upper and lower shield electrode layers can be maintained. As a result, it is possible to suppress an influence of output caused by magnetic field leakage from adjacent tracks (crosstalk).

The above-described and other objects, characteristics, and advantages of the present invention will become clear from the following description with reference to accompanying drawings which show examples of the present invention.

### BRIEF DESCRIPTION OF THE DRAWINGS

FIG. 1 is a schematic perspective drawing showing a magneto-resistance effect element according to one embodiment of the present invention;

FIG. 2A is a side elevation of the magneto-resistance effect element, as seen from the 2A-2A direction in FIG. 1;

FIG. 2B is a cross-sectional view of the magneto-resistance effect element along the 2B-2B line in FIG. 1;

FIG. 2C is cross-sectional view of the magneto-resistance effect element along the 2C-2C line in FIG. 2A;

FIG. 3 is a schematic plot showing operational principles of the magneto-resistance effect element shown in FIG. 1;

FIG. 4A is a plan view of the magneto-resistance effect element according to one example, as seen from an upper shield electrode layer side;

FIG. 4B is a side elevation of the magneto-resistance effect element shown in FIG. 4A, as seen from air bearing surface ABS;

FIG. 5 is a plan view showing a lower shield electrode layer included in the magneto-resistance effect element shown in FIG. 4A;

FIG. 6 is a plot showing a distribution of magnetic flux density generated by the lower shield electrode layer shown in FIG. 5;

FIG. 7A is diagram showing a distribution of magnetic flux density generated by the lower shield electrode layer in contact with a lower gap adjustment layer;

FIG. 7B is an enlargement showing a region adjacent to the lower gap adjustment layer of FIG. 7A;

FIG. 8 is a plan view showing a lower shield electrode layer included in a magneto-resistance effect element according to another example;

FIG. 9 is a cross-sectional diagram showing a thin film magnetic head in a plane that is perpendicular to an air bearing surface (ABS);

FIG. 10 is a plan view of a wafer for manufacturing the magneto-resistance effect element of the present invention;

FIG. 11 is a perspective view of a slider of the present invention;

FIG. 12 is a perspective view of a head arm assembly including a head gimbal assembly equipped with the slider of the present invention;

FIG. 13 is a side elevation showing the head arm assembly equipped with the slider of the present invention; and

FIG. 14 is a plan view of a hard disk drive equipped with the slider of the present invention.

### DETAILED DESCRIPTION OF THE PREFERRED EMBODIMENTS

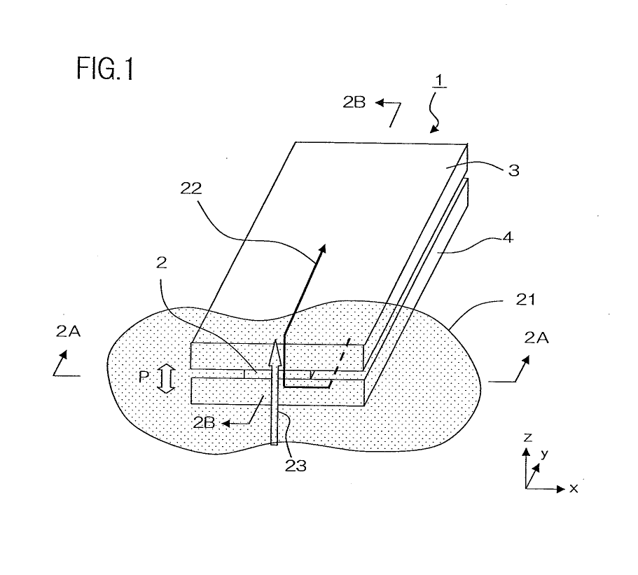

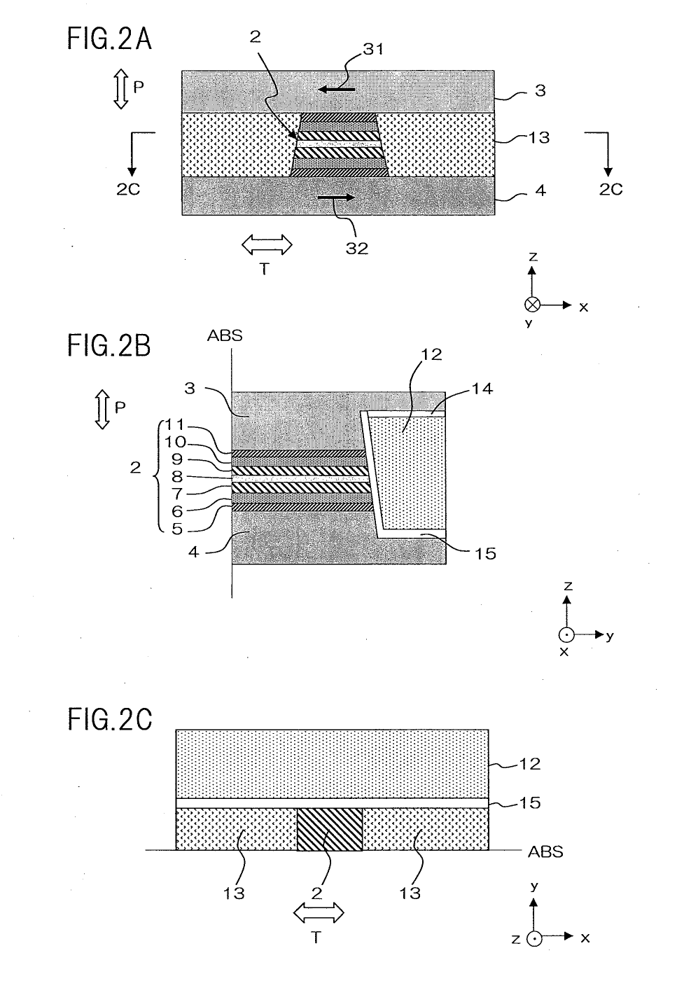

The following describes one embodiment of the present invention with reference to the drawings. A magneto-resistance effect element of the present embodiment is particularly suitable for use as a read head portion of a thin film magnetic head of a hard disc drive. FIG. 1 is a schematic perspective drawing of the magneto-resistance effect element of the present embodiment. FIG. 2A is a side elevation of the magneto-resistance effect element as seen from the 2A-2A direction in FIG. 1, which is to say, from an air bearing surface (a surface lying parallel to the z-x plane in the drawing). FIG. 2B is a cross-sectional view of the magneto-resistance effect element along the 2B-2B line in FIG. 1, which is to say at a surface perpendicular to a track width direction T (a surface lying parallel to the y-z plane in the drawing). FIG. 2C is a cross-sectional view of the magneto-resistance effect element along the 2C-2C line in FIG. 2A, which is to say, at a surface aligned with the layer surface of the MR stack (a surface lying parallel to the x-y plane in the drawing), viewed from above the stacking direction P of the MR stack. An Air Bearing Surface (ABS) is refers to the surface of magneto-resistance effect element 1 that faces recording medium 21.

Magneto-resistance effect element 1 includes MR stack 2, upper shield electrode layer 3 and lower shield electrode layer 4 provided so as to sandwich MR stack 2 in a stacking direction of MR stack 2, bias magnetic layer 12 provided on a surface of MR stack 2 an the opposite side of air bearing surface ABS, and insulating layer 13 provided on both sides of MR stack 2 in track width direction T.

MR stack 2 includes upper magnetic layer 9, lower magnetic layer 7, and non-magnetic intermediate layer 8 sandwiched between upper magnetic layer 9 and lower magnetic layer 7. Lower magnetic layer 7 and upper magnetic layer 9 are free layers in which the magnetization direction changes according to an external magnetic field.

MR stack 2 further includes upper gap adjustment layer 11 and lower gap adjustment layer 5 at respective ends in stacking direction P. Moreover, MR stack 2 includes upper exchange coupling transmission layer 10 which indirectly causes exchange coupling between upper magnetic layer 9 and upper gap adjustment layer 11, and lower exchange coupling transmission layer 6 which indirectly causes exchange coupling between lower magnetic layer 7 and lower gap adjustment layer 5. Upper and lower gap adjustment layers 11 and 5 are made of materials having a higher magnetic permeability and a lower saturation magnetic flux density than upper and lower shield electrode layers 3 and 4 respectively.

MR stack 2 is sandwiched between upper shield electrode layer 3 and lower shield electrode layer 4, and an end portion thereof is exposed on air bearing surface ABS. A voltage applied between upper shield electrode layer 3 and lower shield electrode layer 4 causes sense current 22 to flow in stacking direction P (a direction perpendicular to the layer surface) of MR stack 2. A magnetic field of recording medium 21, which is located opposite to MR stack 2, varies as recording medium 21 moves in movement direction 23. This variation in the magnetic field is detected as variations in electrical resistance based on the magneto-resistance effect. Magneto-resistance effect element 1 makes use of this principle to read magnetic information which has been written to the domains of recording medium 21.

Table 1 shows an example of layer structure for MR stack 2. Table 1 shows the layers in order from bottom to top, starting from lower gap adjustment layer 5 on the side of lower shield electrode layer 4 and working towards upper gap adjustment layer 11 on the side of upper shield electrode layer 3. MR stack 2 is constructed by stacking lower gap adjustment layer 5, lower exchange coupling transmission layer 6, lower magnetic layer 7, non-magnetic intermediate layer 8, upper magnetic layer 9, upper exchange coupling transmission layer 10, and upper gap adjustment layer 11 onto lower shield electrode layer 4 that is composed of an 80Ni20Fe layer at a thickness of approximately 1 μm. Here the values before the element symbols denote atomic percentages of the respective elements. Upper shield electrode layer 3 composed of an 80Ni20Fe layer at a thickness of approximately 1 μm is formed on upper gap adjustment layer 11. Upper shield electrode layer 3 and lower shield electrode layer 4 act as electrodes for supplying sense current 22 in stacking direction P of MR stack 2 and also as shield layers to provide shielding against the magnetic fields of adjacent bits on the same track of recording medium 21.

TABLE 1

| Layer Structure | Composition | Thickness (nm) |
|---|---|---|
| Upper Gap Adjustment Layer 11 | Mo—NiFe | 4.0 |
| Upper Exchange Coupling Transmission | Ru | 1.7 |
| Layer 10 | | |
| Upper Magnetic Layer 9 | CoFe | 1.0 |
| | CoFeB | 2.0 |
| | CoFe | 1.0 |
| Non-magnetic Intermediate Layer 8 | MgO | 1.0 |
| Lower Magnetic Layer 7 | CoFe | 1.0 |
| | CoFeB | 2.0 |
| | CoFe | 1.0 |
| Lower Exchange Coupling Transmission | Ru | 1.7 |
| Layer 6 | | |
| Lower Gap Adjustment Layer 5 | Mo—NiFe | 4.0 |
| | (Total) | 20.4 |

Lower magnetic layer 7 and upper magnetic layer 9 also have a layer structure in which a CoFeB layer is sandwiched between CoFe layers. Lower magnetic layer 7 and upper magnetic layer 9 are free layers in which the magnetization direction varies according to the external magnetic field. Non-magnetic intermediate layer 8 is composed of an MgO layer with a layer thickness of 1.0 nm. Providing the MgO layer between the pair of free layers causes an increase in the magneto-resistance effect, and thereby improves the output of magneto-resistance effect element 1.

One or both of lower magnetic layer 7 and upper magnetic layer 9 can be composed of a CoFe layer in a single layer structure rather than having the composition shown in table 1. Moreover, non-magnetic intermediate layer 8 may use a ZnO layer or Al₂O₃ layer rather than the material shown in table 1. Thus, various materials which allow a high magneto-resistance ratio to be achieved can be used as the non-magnetic intermediate layer. Upper gap adjustment layer 11 is composed of a Mo—NiFe layer which is 80Ni20Fe to which approximately 5 atomic percent of Mo has been added, and upper gap adjustment layer 11 has a higher magnetic permeability and a lower saturation flux density than upper shield electrode layer 3. Lower gap adjustment layer 5 is composed of a Mo-NiFe layer which is 80Ni20Fe to which approximately 5 atomic percent of Mo has been added, and lower gap adjustment layer 5 has a higher magnetic permeability and a lower saturation flux density than lower shield electrode layer 4.

Upper and lower gap adjustment layers 11 and 5 can, in place of the material shown in table 1, use NiFe to which at least one material selected from Mo, Nb, Ta, Ti, and Zi has been added. Upper and lower gap adjustment layers 11 and 5 can use materials having a higher magnetic permeability and a lower saturation magnetic flux density than upper and lower shield electrode layers 3 and 4 respectively.

Upper shield electrode layer 3 is magnetized by a later-described magnetization controller, and magnetization direction 31 lies parallel to track width direction T. Since upper gap adjustment layer 11 has a higher magnetic permeability than upper shield electrode layer 3, upper gap adjustment layer 11 is magnetized in a direction parallel to magnetization direction 31 of upper shield electrode layer 3. Lower shield electrode layer 4 is magnetized by the later-described magnetization controller in a similar manner, and resulting magnetization direction 32 is anti-parallel to magnetization direction 31 of upper shield electrode layer 3. Hence, lower gap adjustment layer 5 is magnetized in a direction that is anti-parallel to the magnetization direction of upper gap adjustment layer 11.

Upper and lower exchange coupling transmission layers 10 and 6 are composed of Ru layers. Upper and lower exchange coupling transmission layers 10 and 6 cause anti-ferromagnetic exchange coupling between upper gap adjustment layer 11 and upper magnetic layer 9 and between lower gap adjustment layer 5 and lower magnetic layer 7 respectively. Hence, in the absence of a bias magnetic field emitted from bias magnetic layer 12, the magnetization direction of upper magnetic layer 9 is anti-parallel to the magnetization direction of upper gap adjustment layer 11. Similarly, in the absence of the bias magnetic field, the magnetization direction of lower magnetic layer 7 is anti-parallel to the magnetization direction of lower gap adjustment layer 5. Thus, in the absence of a bias magnetic field, the magnetization directions of upper magnetic layer 9 and lower magnetic layer 7 are anti-parallel to each other.

Bias magnetic layer 12 is provided to face an opposite surface of air bearing surface ABS of MR stack 2. Bias magnetic layer 12 is formed between lower shield electrode layer 4 and upper shield electrode layer 3. Bias magnetic layer 12 is composed of a CoPt layer at a thickness of 30 nm. Gap layer 15, which is composed of an insulator, is formed between bias magnetic layer 12 and lower shield electrode layer 4. As shown in FIG. 2B, gap layer 15 is also formed at a side of MR stack 2, thereby preventing sense current 22 from flowing in bias magnetic layer 12.

Cap layer 14 is formed between bias magnetic layer 12 and upper shield electrode layer 3. Cap layer 14 may be an insulating layer or a non-magnetic metal layer. Cap layer 14 prevents sense current 22 from flowing in bias magnetic layer 12.

Bias magnetic layer 12 applies a bias magnetic field to MR stack 2, and in particular, to upper magnetic layer 9 and lower magnetic layer 7, in a direction perpendicular to air bearing surface ABS. A relative angle between the magnetization directions of upper magnetic layer 9 and lower magnetic layer 7 is then approximately 90° in an initial magnetization state (a state in which only the bias magnetic field is applied).

Insulating layer 13 composed of Al₂O₃ is provided at both sides of MR stack 2 in track width direction T. Insulating layer 13 also prevents sense current 22 from flowing in bias magnetic layer 12.

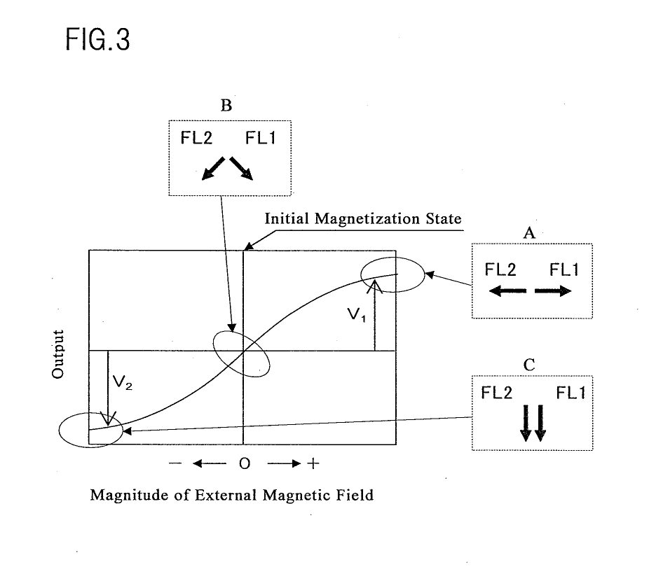

FIG. 3 is a schematic plot showing principles of operation of the magneto-resistance effect element of the present embodiment. The magnitude of the external magnetic field is plotted on the horizontal axis and signal output is plotted on the vertical axis. In the plot, the magnetization direction of upper magnetic layer 9 and the magnetization direction of lower magnetic layer 7 are denoted by FL1 and FL9 respectively. In the absence of a bias magnetic field emitted from bias magnetic layer 12 and an external magnetic field emitted from recording medium 21, the magnetization directions of upper magnetic layer 9 and lower magnetic layer 7 are anti-parallel to each other as described above. Since in reality a bias field is applied, the magnetization direction of upper magnetic layer 9 and the magnetization direction of lower magnetic layer 7 rotate from the anti-parallel state towards the parallel state so that the relative angle formed between the magnetization directions of upper magnetic layer 9 and lower magnetic layer 7 is 90° (see section B in the plot) in the initial state. Then, when the external magnetic field is applied from recording medium 21, the relative angle between the magnetization direction of upper magnetic layer 9 and the magnetization direction of lower magnetic layer 7 increases (towards the anti-parallel state) or decreases (towards the parallel state) according to the direction of the external magnetic field. The closer the magnetization directions move towards the anti-parallel state, the more likely it is that electrons supplied from the electrode will scatter, causing the electrical resistance to sense current 22 to increase (section A in the plot). The closer the magnetization directions move towards the parallel state, the less likely it is that electrons supplied from the electrode will scatter, causing the electrical resistance to sense current 22 to decrease (section C in the plot). In this way, the external magnetic field can be detected by making use of variation in the relative angle between the magnetization direction of upper magnetic layer 9 and the magnetization direction of lower magnetic layer 7.

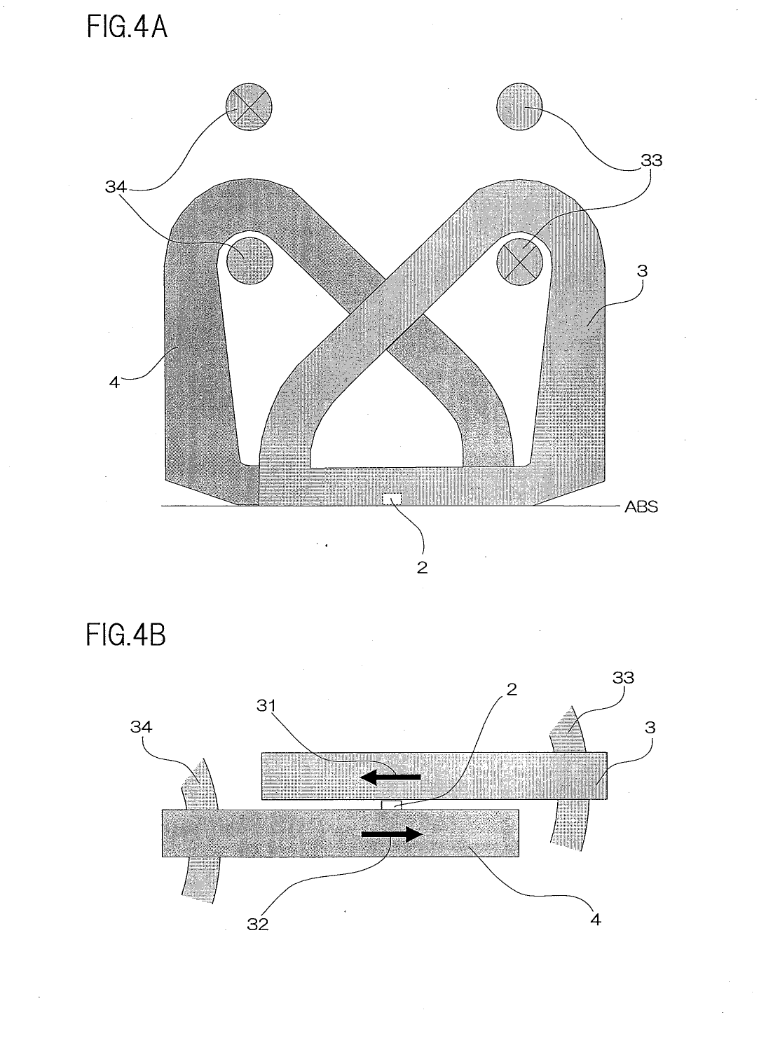

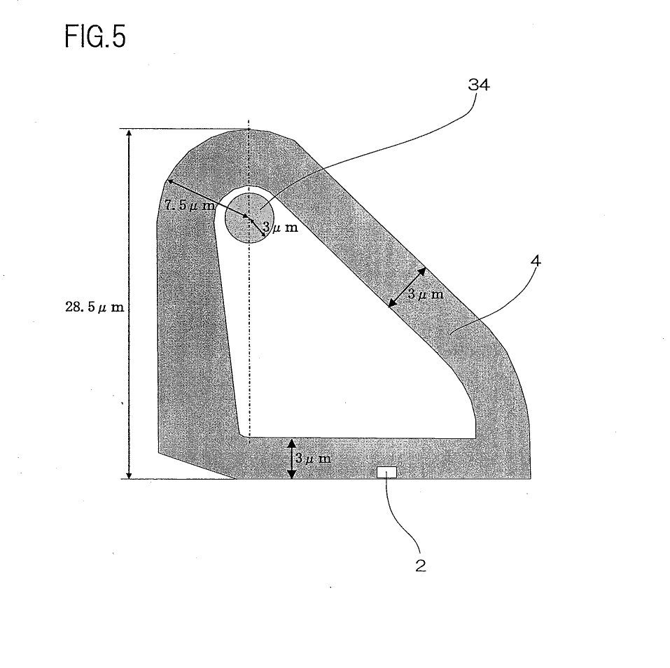

The following describes an example of the magnetization controller which causes magnetization of the upper and lower shield electrode layers 3 and 4. As an example, the following describes details of upper and lower shield electrode layers 3 and 4 and the magnetization controller in detail. FIG. 4A is a plan view of the magneto-resistance effect element of the present example, as seen from the side of upper shield electrode layer 3, and FIG. 4B is side elevation of the magneto-resistance effect element, as seen from air bearing surface ABS. FIG. 5 is a plan view showing lower shield electrode layer 4 included in the magneto-resistance effect element, and shows sizes of various parts. The structure of MR stack 2 is the same as the structure of the above described embodiment (see Table 1).

Upper and lower shield electrode layers 3 and 4 are each 1 μm thick and ring-like in shape when viewed from above. Upper and lower shield electrode layers 3 and 4 are each composed of 80Ni20Fe and have a saturation magnetic flux density of 1 T. Coils 33 and 34 with radii of 3 μm and composed of Cu are wound, as magnetization controllers, onto upper and lower shield electrode layers 3 and 4 respectively at portions which are as distant as possible from air bearing surface ABS. Upper and lower shield electrode layers 3 and 4 are magnetized by current flowing in coils 33 and 34. By having the current flow in opposing directions in coils 33 and 34, the magnetization directions of upper and lower shield electrode layers 3 and 4 in regions where MR stack 2 is provided are caused to be anti-parallel to each other. Moreover, by changing the magnitude of the currents, it is possible to control the degree of the magnetization of upper and lower shield electrode layers 3 and 4.

To reduce Barkhausen noise, upper and lower magnetic layers 9 and 7 are preferably partitioned into single domains. For this, it is preferable that magnetization reaches saturation in upper and lower gap adjustment layers 11 and 5 which exchange couple with upper and lower magnetic layers 9 and 7. When upper and lower gap adjustment layers 11 and 5 do not have a higher magnetic permeability and a lower saturation magnetic flux density than upper and lower shield electrode layers 3 and 4, it is necessary to cause saturation in the magnetization of upper and lower shield electrode layers 3 and 4 in order to enable saturation to occur in the magnetization of upper and lower gap adjustment layers 11 and 5. However, when shield electrode layers 3 and 4 are magnetized to saturation, the shielding effect which shields against the magnetic field leakage from adjacent bits is reduced. Hence, it is preferable that upper and lower gap adjustment layers 11 and 5 are composed of materials having a higher magnetic permeability and a lower saturation magnetic flux density than upper and lower shield electrode layers 3 and 4.

Upper and lower gap adjustment layers 11 and 5 in the present example are composed of Mo—NiFe layers as shown in Table 1. Upper and lower gap adjustment layers 11 and 5 each have dimension 500 nm in track width direction T and 500 nm in a direction perpendicular to air bearing surface ABS. The layers sandwiched between upper and lower gap adjustment layers 11 and 5 have a dimension of 40 nm in track width direction T and 40 nm in a direction perpendicular to air bearing surface ABS. Increasing the sizes of upper and lower gap adjustment layers 11 and 5 in this way makes it easier to partition upper and lower magnetic layers 9 and 7 into single domains.

Upper gap adjustment layer 11 has a magnetic permeability of 100000 and a saturation flux density of 0.7 T. Thus, upper gap adjustment layer 11 has higher magnetic permeability and lower saturation flux density than the NiFe layer provided as upper shield electrode layer 3. Similarly, lower gap adjustment layer 5 has a magnetic permeability of 100000 and a saturation flux density of 0.7 T. Thus, lower gap adjustment layer 5 has a higher magnetic permeability and lower saturation flux density than the NiFe layer provided as lower shield electrode layer 4. Hence, the magnetic flux is concentrated in upper and lower gap adjustment layers 11 and 5, and the magnetization of upper and lower gap adjustment layers 11 and 5 is saturated. As a result, upper and lower gap adjustment layers 11 and 5 are partitioned into single domains, and upper and lower magnetic layers 9 and 7 which exchange couple with upper and lower gap adjustment layers 11 and 5 respectively are partitioned into single domains. On the other hand, in regions adjacent to upper and lower gap adjustment layers 11 and 5, the magnetic flux density of upper and lower shield electrode layers 3 and 4 is reduced. As a result, upper and lower shield electrode layers 3 and 4 provide a sufficient shielding effect.

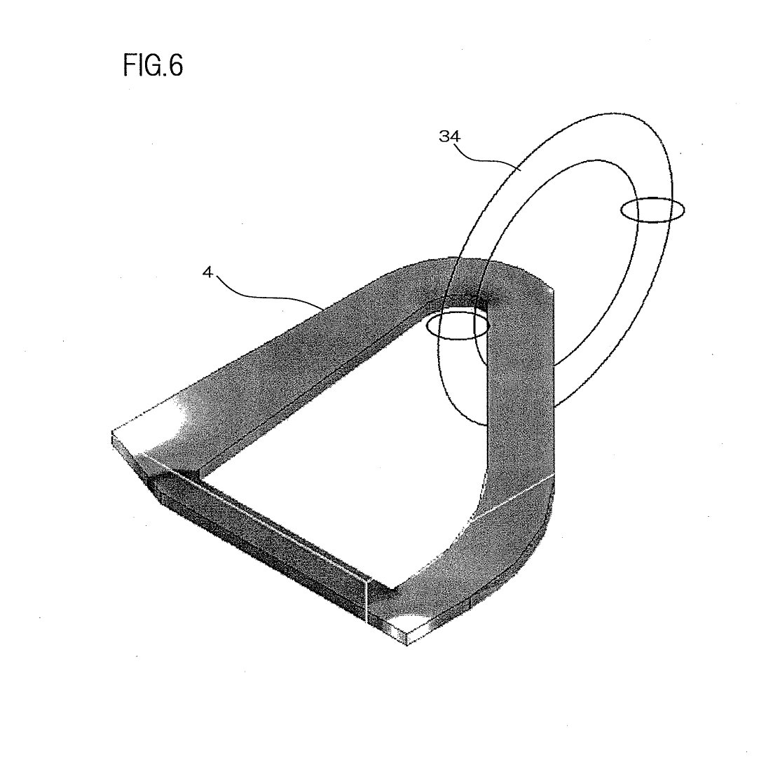

The following describes results from analysis of the flux density in the case in which a Mo-NiFe layer is provided as lower gap adjustment layer 5 and in the case in which such a Mo-NiFe layer is not provided. FIG. 6 shows a magnetic flux density distribution generated in lower shield electrode layer 4 in the case in which lower gap adjustment layer 5 is not provided. FIG. 6 shows the results for a case in which the current flowing in the coil is 10 mA, and depth in figure expresses the strength of the magnetic flux density. In the regions that would be adjacent to MR stack 2, the magnetic flux density in lower shield electrode layer 4 is high, taking a value of approximately 0.8 T. When the magnetic permeability of lower gap adjustment layer 5 is less than the magnetic permeability of lower shield electrode layer 4, the magnetic flux density distribution generated in lower shield electrode layer 4 is considered to be largely unchanged from that shown in FIG. 6. Hence, there is a possibility that the shielding effect of lower shield electrode layer 4 will be reduced.

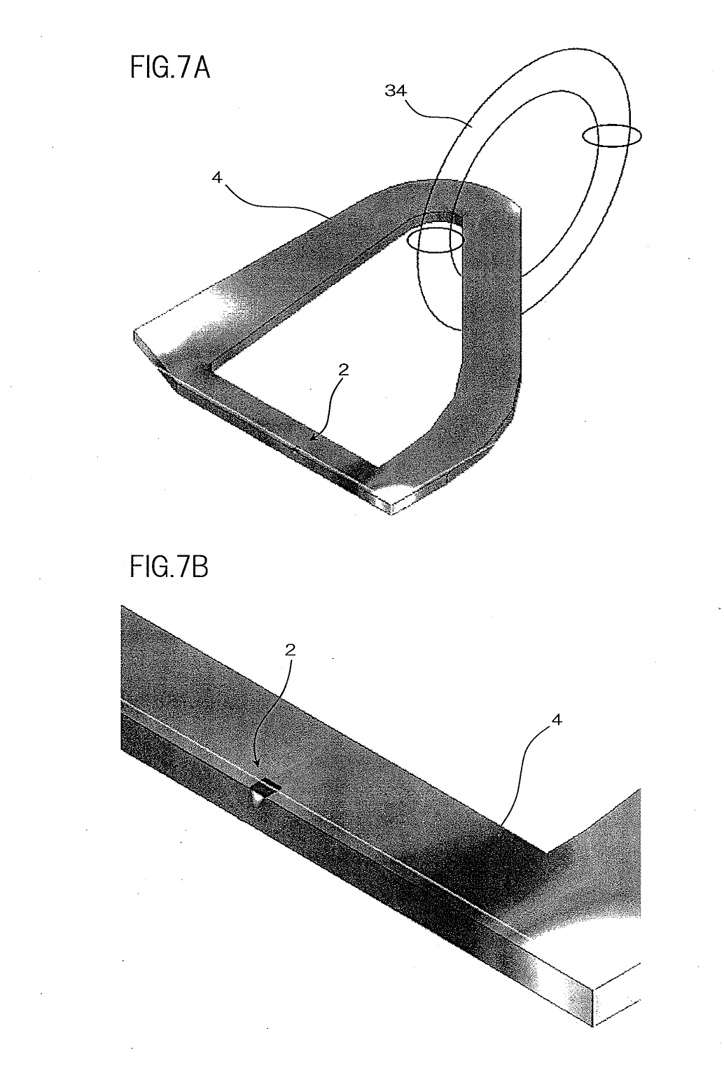

FIG. 7A shows a distribution of magnetic flux density generated in lower shield electrode layer 4 shown in FIG. 5 in the case in which a Mo—NiFe layer is provided as lower gap adjustment layer 5. FIG. 7B is an enlargement of a region in proximity to lower gap adjustment layer 5. The drawing shows the results for when a current of 10 mA flows in a coil. As shown in the drawing, the magnetization of lower gap adjustment layer 5 is saturated. As a result, it is possible to partition lower magnetic layer 7 into single domains and reduce the Barkhausen noise. Also, because the magnetic flux is concentrated in lower gap adjustment layer 5, the magnetic flux density in regions of lower shield electrode layer 4 adjacent to lower gap adjustment layer 5 is significantly reduced to approximately 0.35 T or less. Consequently, lower shield electrode layer 4 provides a sufficient shielding effect. The above-described results are also applicable to upper shield electrode layer 3 and upper gap adjustment layer 11.

The following describes results from when magneto-resistance effect element 1 of the present example is actually manufactured and the element characteristics are measured. To show the effect of the Mo—NiFe layers provided as upper and lower gap adjustment layers 11 and 5, a magneto-resistance effect element having the MR stack shown in Table 2 was manufactured as a comparative example, and the measured results were compared. The MR stack of the comparative example includes, between the upper magnetic layer and the upper shield electrode layer and in layer order from the bottom upwards, an exchange coupling transmission layer, a gap adjustment layer, an exchange coupling transmission layer, and a gap adjustment layer. Moreover, the MR stack of the comparative example includes, between the lower magnetic layer and the lower shield electrode layer and in layer order from the bottom upwards, a gap adjustment layer, an exchange coupling transmission layer, a gap adjustment layer, and an exchange coupling transmission layer. The gap adjustment layer is composed of a CoFe layer and has a lower magnetic permeability than the shield electrode layers which are composed of NiFe. The other layer structures are the same as the layer structures of the present embodiment. The total layer thickness in the comparative example is identical to the total layer thickness of the present example. Further, the form and dimensions of the upper and lower shield electrode layers and bias magnetic layers in the comparative example are the same as those of the present example.

TABLE 2

| Layer Structure | Composition | Thickness (nm) |
|---|---|---|
| Gap Adjustment Layer | CoFe | 1.7 |
| Exchange Coupling Transmission Layer | Ru | 0.8 |
| Gap Adjustment Layer | CoFe | 1.5 |
| Exchange Coupling Transmission Layer | Ru | 1.7 |
| Upper Magnetic Layer | CoFe | 1.0 |
| | CoFeB | 2.0 |
| | CoFe | 1.0 |
| Non-magnetic Intermediate Layer | MgO | 1.0 |
| Lower Magnetic Layer | CoFe | 1.0 |
| | CoFeB | 2.0 |
| | CoFe | 1.0 |
| Exchange Coupling Transmission Layer | Ru | 1.7 |
| Gap Adjustment Layer | CoFe | 1.5 |
| Exchange Coupling Transmission Layer | Ru | 0.8 |
| Gap Adjustment Layer | CoFe | 1.7 |
| | (Total) | 20.4 |

A standard deviation of asymmetry of an output waveform and a half-width of the output waveform were measured as characteristics of the magneto-resistance effect element, and results for the present example and the comparative example were compared. The asymmetry of the output wave-form is defined by the formula “(|V₁|−|V₂|)/(|V₁+|V₂|)×100”. Here V₁ is the output (the difference from the output in the initial magnetization state) when a positive external magnetic field is applied and V₂ is the output (the difference from the output in the initial magnetization state) when a minus magnetic field is applied (see FIG. 3). Thus, the asymmetry is an indicator showing a degree of non-linearity in the response to the external magnetic field. The standard deviation of the asymmetry shows variation in the non-linearity over a plurality of elements, and serves as an indicator of variation in the magnetization directions of the upper and lower magnetic layers.

The “half-width” is defined as the half-width of the output wave-form when reading a recording medium on which a single pulse signal has been recorded. Hence, a smaller half-width indicates a larger shielding effect against fringe-field emitted from adjacent bits.

Table 3 shows standard deviations of asymmetry and half-widths of the output wave-form in the magneto-resistance effect elements of the example and the comparative example. The standard deviation of asymmetry shown in Table 3 was found using measurements on 30 units of magneto-resistance effect element 1. Note that, in Table 3, the value of the half-width in the example has been normalized to “1”.

TABLE 3

| | | Standard Deviation of | Normalized |
|---|---|---|---|
| | Current (mA) | Asymmetry (%) | Half-width |
| Present Example | 10 | 12 | 1.00 |
| Comparative | 10 | 17 | 1.00 |
| Example | 20 | 12 | 1.70 |

When the coil current is 10 mA, the half-width in magneto-resistance effect element 1 of the example is the same as the half-width of the magneto-resistance effect element in the comparative example. However, in magneto-resistance effect element 1 of the example, the standard deviation of the asymmetry is lower than in the comparative example. This is because the variation in the magnetization of upper and lower magnetic layers 9 and 7 has been reduced by saturating the magnetization of upper and lower gap adjustment layers 11 and 5.

When the coil current is 20 mA in the comparative example, the magnetic flux density in the shield electrode layers reaches approximately 1 T, and the magnetization is saturated. Hence, the standard deviation of the asymmetry is reduced, while the half-width is increased. In other words, the shielding effect of the shield electrode layers is reduced. Hence, it can be stated that magneto-resistance effect element 1 of the example simultaneously reduces both the standard deviation of the asymmetry and the half-width. As a result, it possible to provide a thin film magnetic head which operates with a narrow read gap.

Table 4 shows characteristics of the element in which the thickness of upper and lower gap adjustment layers 11 and 5 is different from that of the magneto-resistance effect element of the present example. When the layer thickness is increased, there is no significant change in the standard deviation of the asymmetry, but the half-width of the output wave-form lengthens. This is because upper and lower gap adjustment layers 11 and 5 whose magnetization is saturated do not provide a shielding effect but do have the effect of adjusting a width of the gap between the shields. Hence, it is preferable that the layer thicknesses of upper and lower gap adjustment layers 11 and 5 are thin.

TABLE 4

| Thickness of | Standard Deviation | |
|---|---|---|
| Mo—NiFe Layer (nm) | of Asymmetry (%) | Normalized Half-width |
| 4 | 12 | 1.00 |
| 5 | 12 | 1.15 |

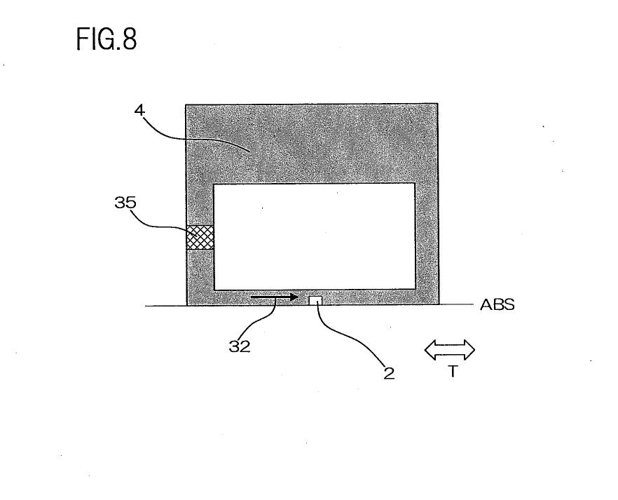

The magneto-resistance effect element of the present invention has been described in detail above. However, the present invention is not limited to the embodiments and examples described above. For instance, FIG. 8 is a plan view showing a lower shield electrode layer included in a magneto-resistance effect element according to another example. FIG. 8 shows a permanent magnet 35 being used as the magnetization controller. Lower shield electrode layer 4 has a ring-like shape, and permanent magnet 35 is provided in a portion of lower shield electrode layer 4. Lower shield electrode layer 4 is magnetized by permanent magnet 35, and magnetization direction 32 lies parallel to track width direction T. An upper shield electrode layer 3 having a similar structure is constructed so that the magnetization direction of upper shield electrode layer 3 is anti-parallel to magnetization direction 32 of lower shield electrode layer 4. In this way, permanent magnets may be used as the magnetization controller.

Further, for upper and lower exchange coupling transmission layers 10 and 6, at least one material selected from Ru, Rh, Ir, Cr, Cu, Ag, Au, Pt, and Pd can be used in place of the material showed in Table 1. By selecting from among these materials and setting material thicknesses, it is possible to adjust the strength of the exchange coupling between upper magnetic layer 9 and upper gap adjustment layers 11 and between lower magnetic layers 7 and lower gap adjustment layers 5. It is also possible to adjust whether the exchange coupling is anti-ferromagnetic or ferromagnetic. When the exchange coupling is ferromagnetic, the magnetization directions of upper and lower magnetic layers 9 and 7 lie parallel to the magnetization directions of upper and lower gap adjustment layers 11 and 5. In this case, the magnetization directions of upper and lower shield electrode layers 3 and 4 should be controlled so that the magnetization directions of upper magnetic layer 9 and lower magnetic layer 7 are anti-parallel to each other.

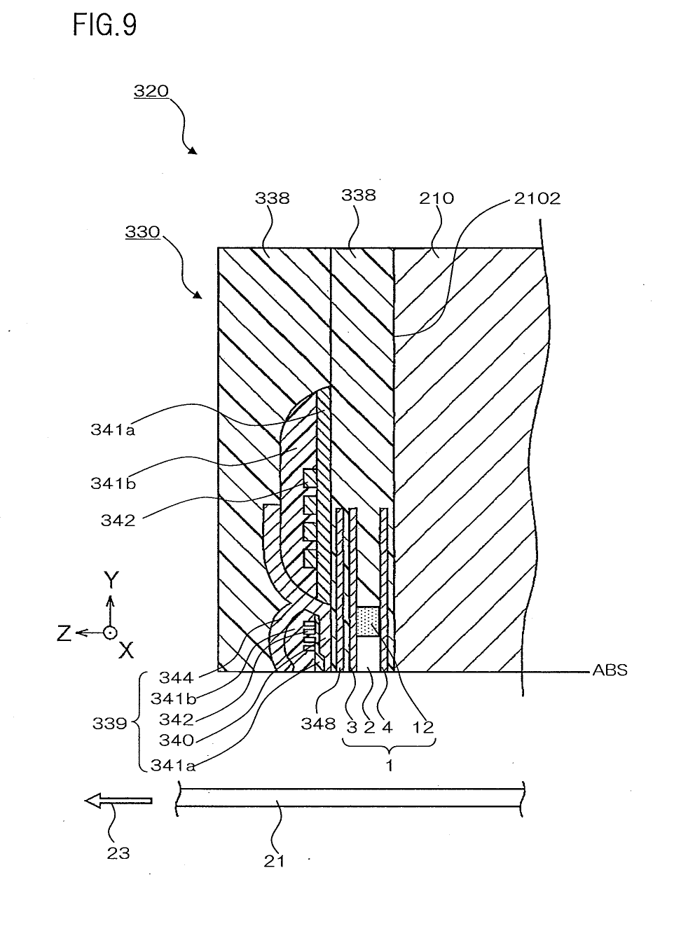

The following describes a thin film magnetic head in which the above-described magneto-resistance effect element has been used. FIG. 9 is a cross-sectional diagram through the thin film magnetic head in a direction perpendicular to air bearing surface ABS. Note, however, that the magnetization controllers which control the magnetization directions of the upper and lower shield electrode layers are not shown in FIG. 9. As shown in FIG. 9, thin film magnetic head 320 includes slider 210 which is mainly composed of ALTIC (AL₂O₃—TiC), and magnetic head part 330. Magnetic head part 330 is provided on side surface 2102 of slider 210. Magnetic head part 330 includes magneto-resistance effect element 1 as a reproducing element and electromagnetic coil device 339 as an inductive-type electromagnetic conversion device.

The layers of MR stack 2 which forms magneto-resistance effect element 1 are provided to be substantially parallel to a side surface of slider 210, and lower shield electrode layer 4 is arranged to be closer to slider 210 than upper shield electrode layer 3. Upper and lower shield electrode layers 3 and 4 and MR stack 2 form a portion of air bearing surface ABS.

Device intermediate shield layer 348 composed of the same material as upper shield electrode layer 3 is formed between upper shield electrode layer 3 and electromagnetic coil device 339. Device intermediate shield layer 348 shields magneto-resistance effect element 1 from the magnetic field generated by electromagnetic coil device 339, and thereby reduces noise at readout. Further, a backing coil may be formed between device intermediate shield layer 348 and electromagnetic coil device 339. The backing coil generates magnetic flux which negates the magnetic flux loop via upper and lower shield electrode layers 3 and 4. As a result, it is possible to achieve suppression of the wide adjacent track erasure (WATE) phenomenon which entails unnecessary writing or deletion operations to recording medium 21.

Insulating layer 338 is formed between upper shield electrode layer 3 and device intermediate shield layer 348, between device intermediate shield layer 348 and electromagnetic coil device 339, and between lower shield electrode layer 4 and slider 210.

Electromagnetic coil device 339 is preferably a perpendicular magnetic recording-use coil. Electromagnetic coil device 339 includes main magnetic pole layer 340, gap layer 341a, coil insulating layer 341b, coil layer 342, and auxiliary magnetic pole layer 344. Main magnetic pole layer 340 leads magnetic flux induced by coil layer 342 to a recording layer of magnetic recording medium 21. Here, it is preferable that a width in the track-with direction (X-direction in the drawings) and a thickness in the layer direction (Z-direction in the drawings) of the end portion of main magnetic pole layer 340 on air bearing surface ABS side are smaller than at other portions of main magnetic pole layer 340. Such an arrangement allows generation of a fine ferromagnetic field for supporting a high recording density.

The end portion of auxiliary magnetic pole layer 344 on air bearing surface ABS side which is magnetically coupled to main magnetic pole layer 340 forms a trailing shield part having a cross-sectional surface which is wider than other portions of auxiliary magnetic pole layer 344. Auxiliary magnetic pole layer 344 faces the end portion of main magnetic pole layer 340 on air bearing surface ABS side via gap layer 341a and coil insulating layer 341b.

Gap layer 341a and coil insulating layer 341b are formed using an insulator such as alumina. By providing auxiliary magnetic pole layer 344, the magnetic field gradient between auxiliary magnetic pole layer 344 and main magnetic pole layer 340 in the region of air bearing surface ABS is increased. As a result, jitter in the signal output is reduced, and the error rate during reading is reduced.

The thickness of auxiliary magnetic pole layer 344 is approximately 0.5 to 5 μm, and is constructed from an alloy composed of two or three materials selected from Ni, Fe, and Co, an alloy mainly composed of these materials with other elements added, or the like. Auxiliary magnetic pole layer 344 is formed using, for instance, a frame plating method or a sputtering method.

Gap layer 341a is formed between coil layer 342 and main magnetic pole layer 340, and is composed of A1₂O₃, DLC (Diamond-Like Carbon) or the like, at a thickness of 0.01 to approximately 0.5 μm. To form gap layer 341a, a sputtering method, a CVD method, or the like may be used.

Coil layer 342 is, for instance, formed from Cu or the like at a thickness of approximately 0.5 to approximately 3 μm. To form coil layer 342, a frame plating method or the like may be used. A rear end of main magnetic pole layer 340 is joined to a portion, of auxiliary magnetic pole layer 344, that is positioned away from air bearing surface ABS. Coil layer 342 is formed so as to surround this joint portion.

A coil insulating layer 341 b composed of an insulator, such as a cured aluminum oxide or a resist layer, at a thickness of 0.1 to approximately 5 μm is formed between coil layer 342 and auxiliary magnetic pole layer 344. Insulating layer 338 is formed so as to cover electromagnetic coil device 339 on an opposite side of electromagnetic coil device 339 to the side of slider 210.

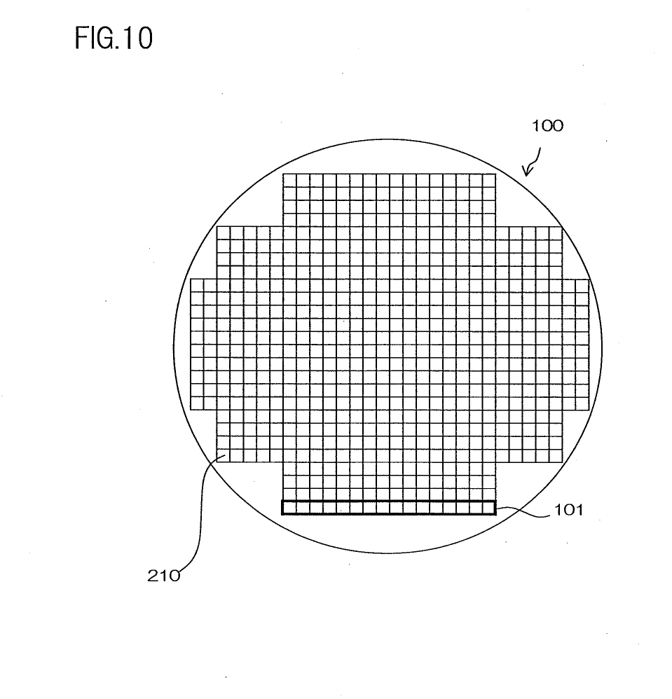

Next, explanation will be made regarding a wafer for fabricating a magnetic field detecting element described above. FIG. 10 is a schematic plan view of a wafer. Wafer 100 has a MR stack which is deposited thereon to form at least magneto-resistance effect element. Wafer 100 is diced into bars 101 which serve as working units in the process of forming air bearing surface ABS. After lapping, bar 101 is diced into sliders 210 which include thin-film magnetic heads. Dicing portions, not shown, are provided in wafer 100 in order to dice wafer 100 into bars 101 and into sliders 210.

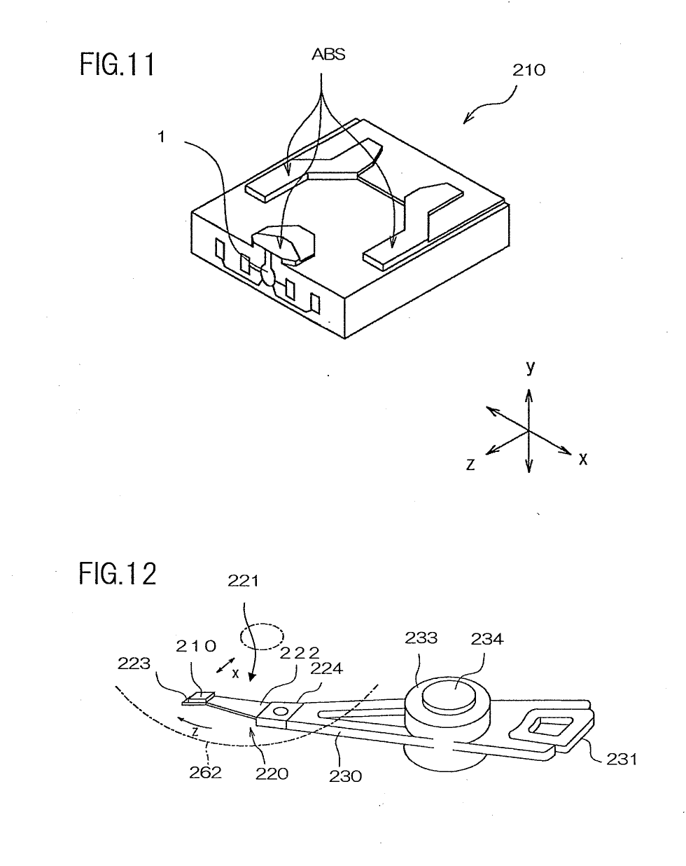

Referring to FIG. 11, slider 210 has a substantially hexahedral shape. One of the six surfaces of slider 210 forms air bearing surface(ABS), which is positioned opposite to the hard disk.

Referring to FIG. 12, head gimbal assembly 220 has slider 210 and suspension 221 for resiliently supporting slider 210. Suspension 221 has load beam 222 in the shape of a flat spring and made of, for example, stainless steel, flexure 223 that is attached to one end of load beam 222, and base plate 224 provided on the other end of load beam 222. Slider 210 is fixed to flexure 223 to provide slider 210 with an appropriate degree of freedom. The portion of flexure 223 to which slider 210 is attached has a gimbal section for maintaining slider 210 in a fixed orientation.

Slider 210 is arranged opposite to hard disk 262, which is a rotationally-driven disc-shaped storage medium, in a hard disk drive. When hard disk 262 rotates in the z direction shown in FIG. 12, airflow which passes between hard disk 262 and slider 210 creates a dynamic lift, which is applied to slider 210 downward in the y direction. Slider 210 is configured to lift up from the surface of hard disk 262 due to this dynamic lift effect. Magneto-resistance effect element 1 is formed in proximity to the trailing edge (the end portion at the lower left in FIG. 11) of slider 210, which is on the outlet side of the airflow.

The arrangement in which head gimbal assembly 220 is attached to arm 230 is called head arm assembly 221. Arm 230 moves slider 210 in transverse direction x with regard to the track of hard disk 262. One end of arm 230 is attached to base plate 224. Coil 231, which constitutes a part of a voice coil motor, is attached to the other end of arm 230. Bearing section 233 is provided in the intermediate portion of arm 230. Arm 230 is rotatably held by shaft 234 which is attached to bearing section 233. Arm 230 and the voice coil motor to drive arm 230 constitute an actuator.

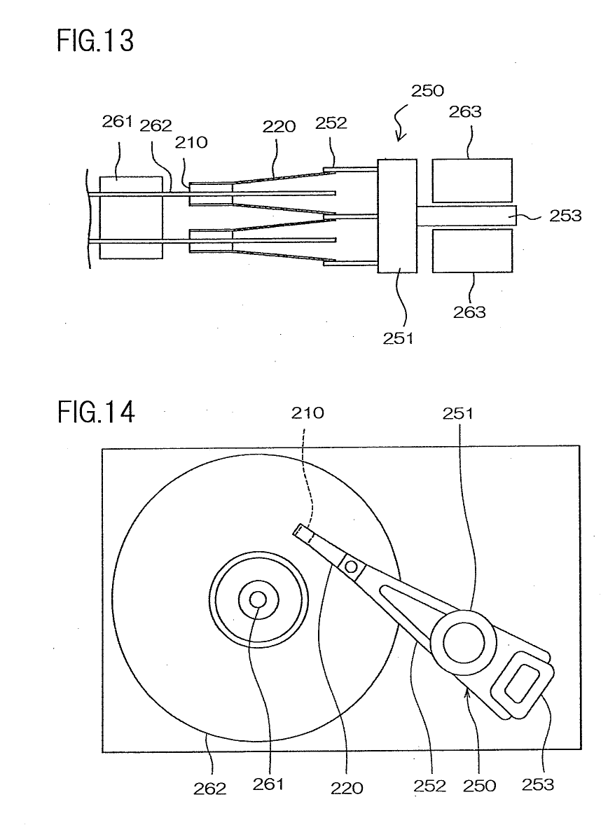

Referring to FIG. 13 and FIG. 14, a head stack assembly and a hard disk drive that incorporate the slider mentioned above will be explained next. The arrangement in which head gimbal assemblies 220 are attached to the respective arm of a carriage having a plurality of arms is called a head stack assembly. FIG. 13 is a side view of a head stack assembly, and FIG. 14 is a plan view of a hard disk drive. Head stack assembly 250 has carriage 251 provided with a plurality of arms 252. Head gimbal assemblies 220 are attached to arms 252 such that head gimbal assemblies 220 are arranged apart from each other in the vertical direction. Coil 253, which constitutes a part of the voice coil motor, is attached to carriage 251 on the side opposite to arms 252. The voice coil motor has permanent magnets 263 which are arranged in positions that are opposite to each other and interpose coil 253 therebetween.

Referring to FIG. 14, head stack assembly 250 is installed in a hard disk drive. The hard disk drive has a plurality of hard disks which are connected to spindle motor 261. Two sliders 210 are provided per each hard disk 262 at positions which are opposite to each other and interpose hard disk 262 therebetween. Head stack assembly 250 and the actuator, except for sliders 210, work as a positioning device in the present invention. They carry sliders 210 and work to position sliders.210 relative to hard disks 262. Sliders 210 are moved by the actuator in the transverse direction with regard to the tracks of hard disks 262, and positioned relative to hard disks 262. Magneto-resistance effect element 1 that is included in slider 210 writes information to hard disk 262 by means of the write head portion, and reads information recorded in hard disk 262 by means of the read head portion.

Although certain preferred embodiments of the present invention have been shown and described in detail, it should be understood that various changes and modifications may be made without departing from the spirit or scope of the appended claims.

1. A magneto-resistance effect element comprising:
a magneto-resistance effect stack including an upper magnetic layer and a lower magnetic layer in which respective magnetization directions change in accordance with an external magnetic field, a non-magnetic intermediate layer sandwiched between the upper and lower magnetic layers, an upper gap adjustment layer and a lower gap adjustment layer provided at respective ends in a direction of stacking the magneto-resistance effect stack, an upper exchange coupling transmission layer configured to generate exchange coupling between the upper magnetic layer and the upper gap adjustment layer, and a lower exchange coupling transmission layer configured to generate exchange coupling between the lower magnetic layer and the lower gap adjustment layer;
an upper shield electrode layer and a lower shield electrode layer which are provided to sandwich the magneto-resistance effect stack therebetween in the direction of stacking the magneto-resistance effect stack, wherein the upper shield electrode layer and the lower shield electrode layer supply sense current in the direction of stacking, and magnetically shield the magneto-resistance effect stack; and
a bias magnetic layer which is provided on a surface of the magneto-resistance effect stack opposite to an air bearing surface, and wherein the bias magnetic layer applies a bias magnetic field to the upper and lower magnetic layers in a direction perpendicular to the air bearing surface, wherein
the upper and lower shield electrode layers are each magnetized in a track width direction by a magnetization controller, and
the upper and lower gap adjustment layers are composed of a material having a higher magnetic permeability and a lower saturation magnetic flux density than the upper and lower shield electrode layers respectively.

2. The magneto-resistance effect element according to claim 1, wherein
the upper and lower shield electrode layers are composed of a NiFe layer.

3. The magneto-resistance effect element according to claim 1, wherein
the upper and lower gap adjustment layers are composed of a material to which at least one material selected from Mo, Nb, Ta, Ti, and Zr has been added.

4. The magneto-resistance effect element according to claim 1, wherein
a thickness of each of the upper and lower gap adjustment layers is 4 nm or less.

5. A slider including the magneto-resistance effect element according to claim 1.

6. A wafer having a magneto-resistance effect stack that is to be formed into the magneto-resistance effect, element according to claim 1.

7. A head gimbal assembly including the slider according to claim 5, and a suspension for resiliently supporting the slider.

8. A hard disk drive including the slider according to claim 5, and a device for supporting the slider and positioning the slider with respect to a recording medium.
